(19) United States
(12) Patent Application Publication
(10) Pub. No.: US 2025/0011929 A1
(43) Pub. Date: Jan. 9, 2025

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Toyama-shi (JP)

(72) Inventors: Arito OGAWA, Toyama-shi (JP); Atsuro SEINO, Toyama-shi (JP)

(73) Assignee: Kokusai Electric Corporation, Toyama-shi (JP)

(21) Appl. No.: 18/884,897

(22) Filed: Sep. 13, 2024

Related U.S. Application Data
(63) Continuation of application No. PCT/JP2022/011713, filed on Mar. 15, 2022.

(51) Int. Cl. C23C 16/455; C23C 16/34; C23C 16/44; C23C 16/52; H01L 21/67

(52) U.S. Cl. CPC C23C 16/45561; C23C 16/34; C23C 16/4408; C23C 16/45544; C23C 16/52; H01L 21/67017

(57) ABSTRACT

A substrate processing quality is improved when supplying different gases simultaneously. There is provided a technique that includes: a process vessel; a first supplier supplying a first gas into the process vessel; a gas pipe conveying a second and a third gas into the process vessel, the third gas having an element of the second gas but a molecular structure thereof differing from the second gas; a storage at the gas pipe to store the second gas and the third gas; a first valve at the gas pipe between the storage and the process vessel; a second and a third gas supplier supplying the second and the third gas into the storage, respectively; and a controller for storing the second and the third gas in the storage, supplying the first gas to a substrate and supplying the second and the third gas to the substrate from the storage.

### CROSS-REFERENCE TO RELATED APPLICATIONS

This application is a bypass continuation application of PCT International Application No. PCT/JP2022/011713, filed on Mar. 15, 2022, in the WIPO, the entire contents of which are hereby incorporated by reference.

### BACKGROUND OF THE INVENTION

### 1. Field

The present disclosure relates to a substrate processing apparatus, a substrate processing method, a method of manufacturing a semiconductor device and a non-transitory computer-readable recording medium.

### 2. Related Art

According to some related arts, as a part of a manufacturing process of a semiconductor device, a step of forming a film on a substrate in a process vessel of a substrate processing apparatus may be performed.

However, in the substrate processing apparatus mentioned above, when a low vapor pressure gas and a high vapor pressure gas are introduced into the process vessel simultaneously, it may not be possible to supply a sufficient amount of the low vapor pressure gas.

### SUMMARY OF THE INVENTION

According to the present disclosure, there is provided a technique capable of improving a processing quality of a substrate even when a plurality of different gases are supplied simultaneously.

According to an embodiment of the present disclosure, there is provided a technique that includes: a process vessel configured to accommodate a substrate; a first gas supplier configured to supply a first reactive gas into the process vessel; a gas supply pipe through which a second reactive gas and a third reactive gas are supplied into the process vessel, wherein the third reactive gas contains an element same as that contained in the second reactive gas and a molecular structure of the third reactive gas is different from that of the second reactive gas; a storage provided at the gas supply pipe and configured to store the second reactive gas and the third reactive gas; a first valve provided at the gas supply pipe between the storage and the process vessel; a second gas supplier configured to supply the second reactive gas into the storage; a third gas supplier configured to supply the third reactive gas into the storage; and a controller configured to be capable of controlling the first gas supplier, the first valve, the second gas supplier and the third gas supplier to perform: (a) storing the second reactive gas and the third reactive gas in the storage; (b) supplying the first reactive gas to the substrate; and (c) supplying the second reactive gas and the third reactive gas to the substrate from the storage.

### BRIEF DESCRIPTION OF THE DRAWINGS

FIG. 1 is a diagram schematically illustrating a vertical cross-section of a vertical type process furnace of a substrate processing apparatus according to one or more embodiments of the present disclosure.

FIG. 2 is a diagram schematically illustrating a horizontal cross-section taken along a line A-A of the substrate processing apparatus shown in FIG. 1.

FIG. 3 is a block diagram schematically illustrating a configuration of a controller and related components of the substrate processing apparatus according to the embodiments of the present disclosure.

FIGS. 4A to 4D are diagrams schematically illustrating operations of a gas supply structure performed in a substrate processing preferably used in the embodiments of the present disclosure.

FIG. 5 is a diagram schematically illustrating a modified example of the operations of the gas supply structure performed in the substrate processing preferably used in the embodiments of the present disclosure.

FIG. 6 is a diagram schematically illustrating another modified example of the operations of the gas supply structure performed in the substrate processing preferably used in the embodiments of the present disclosure.

FIG. 7 is a diagram schematically illustrating still another modified example of the operations of the gas supply structure performed in the substrate processing preferably used in the embodiments of the present disclosure.

### DETAILED DESCRIPTION

### Embodiments of Present Disclosure

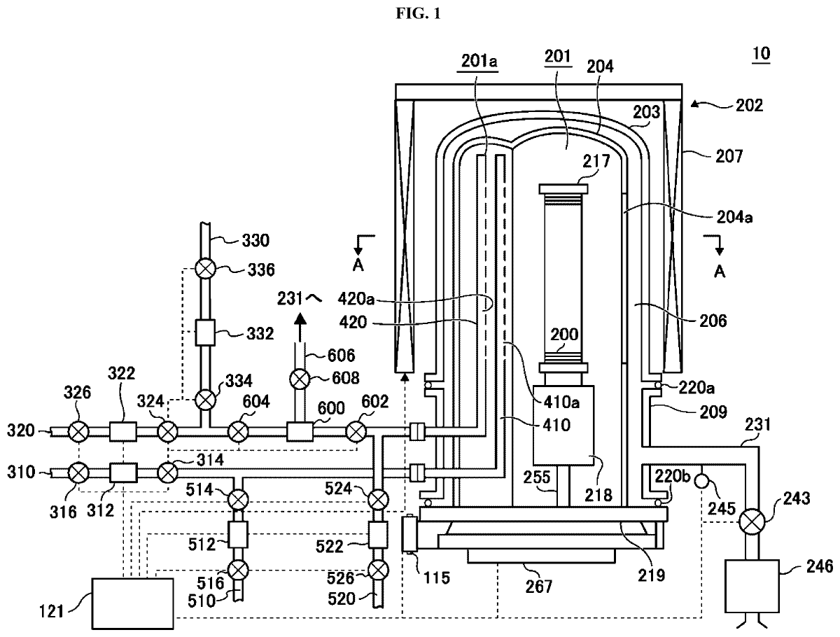

Hereinafter, one or more embodiments (also simply referred to as “embodiments”) of the technique of the present disclosure will be described in detail with reference to FIGS. 1 to 3 and FIGS. 4A to 4D. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

A substrate processing apparatus 10 according to the present embodiments includes a process furnace 202 provided with a heater 207 serving as a heating structure (which is a heating device or a heating system). The heater 207 is of a cylindrical shape, and is vertically installed while being supported by a heater base (not shown) serving as a support plate.

An outer tube 203 constituting a reaction tube (which is a reaction vessel or a process vessel) is provided in an inner side of the heater 207 to be aligned in a manner concentric with the heater 207. For example, the outer tube 203 is made of a heat resistant material such as quartz (SiO₂) and silicon carbide (SiC). The outer tube 203 is of a cylindrical shape with a closed upper end and an open lower end. A manifold (which is an inlet flange) 209 is provided under the outer tube 203 to be aligned in a manner concentric with the outer tube 203. For example, the manifold 209 is made of a metal such as stainless steel (SUS). The manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

An inner tube 204 constituting the reaction vessel is provided in an inner side of the outer tube 203. For example, the inner tube 204 is made of a heat resistant material such as quartz (SiO₂) and silicon carbide (SiC). The inner tube 204 is of a cylindrical shape with a closed upper end and an open lower end. The process vessel (reaction vessel) is constituted mainly by the outer tube 203, the inner tube 204 and the manifold 209. A process chamber 201 is provided in a hollow cylindrical portion of the process vessel (that is, an inside of the inner tube 204).

The process chamber 201 is configured to be capable of accommodating a plurality of wafers including a wafer 200 serving as a substrate in a horizontal orientation to be vertically arranged in a multistage manner by a boat 217 serving as a substrate support. In other words, the process chamber 201 is configured such that the plurality of wafers including the wafer 200 are accommodated in the process vessel. Hereinafter, the plurality of wafers including the wafer 200 may also be simply referred to as “wafers 200”.

Nozzles 410 and 420 are installed in the process chamber 201 so as to penetrate a side wall of the manifold 209 and the inner tube 204. Gas supply pipes 310 and 320 are connected to the nozzles 410 and 420, respectively. However, the process furnace 202 of the present embodiments is not limited to the example described above.

Valves 316 and 326 serving as opening/closing valves, mass flow controllers (MFCs) 312 and 322 serving as flow rate controllers (flow rate control structures) and valves 314 and 324 serving as opening/closing valves are sequentially installed at the gas supply pipes 310 and 320 in this order from upstream sides to downstream sides of the gas supply pipes 310 and 320 in a gas flow direction, respectively. A gas supply pipe 510 through which an inert gas is supplied is connected to the gas supply pipe 310 at a downstream location of the valve 314. A gas supply pipe 330 is connected to the gas supply pipe 320 at a location downstream of the valve 324. A valve 336 serving as an opening/closing valve, a mass flow controller (MFC) 332 serving as a flow rate controller (flow rate control structure) and a valve 334 serving as an opening/closing valve are sequentially installed at the gas supply pipe 330 in this order from an upstream side to a downstream side of the gas supply pipe 330 in the gas flow direction. Further, a valve (which is a second valve) 604 serving as an opening/closing valve, a storage 600 and a valve (which is a first valve) 602 serving as an opening/closing valve are sequentially installed at a location downstream of a connection portion of the gas supply pipe 320 with the gas supply pipe 330 in this order from the upstream side to the downstream side of the gas supply pipe 320 in the gas flow direction. That is, the valve 602 is provided between the storage 600 of the gas supply pipe 320 and the outer tube 203. Further, the valve 604 is provided at a location upstream of the storage 600, that is, between the storage 600 and the connection portion of the gas supply pipe 320 with the gas supply pipe 330. Further, a gas supply pipe 520 through which the inert gas is supplied is connected to the gas supply pipe 320 at a location downstream of the valve 602. Valves 516 and 526 serving as opening/closing valves, MFCs 512 and 522 serving as flow rate controllers (flow rate control structures) and valves 514 and 524 serving as opening/closing valves are sequentially installed at the gas supply pipes 510 and 520 in this order from upstream sides to downstream sides of the gas supply pipes 510 and 520 in the gas flow direction, respectively.

The nozzles 410 and 420 are connected to front ends (tips) of the gas supply pipes 310 and 320, respectively. Each of the nozzles 410 and 420 may be configured as an L-shaped nozzle. Horizontal portions of the nozzles 410 and 420 are installed so as to penetrate the side wall of the manifold 209 and the inner tube 204. Vertical portions of the nozzles 410 and 420 are installed in a preliminary chamber 201a of a channel shape (a groove shape) protruding outward in a radial direction of the inner tube 204 and extending in the vertical direction. That is, the vertical portions of the nozzles 410 and 420 are installed in the preliminary chamber 201a to extend upward along an inner wall of the inner tube 204 (in a direction in which the wafers 200 are arranged).

The nozzles 410 and 420 extend from a lower region of the process chamber 201 to an upper region of the process chamber 201. The nozzles 410 and 420 are provided with a plurality of gas supply holes 410a and a plurality of gas supply holes 420a at positions facing the wafers 200, respectively. Thereby, a gas such as a process gas can be supplied to the wafers 200 through the gas supply holes 410a of the nozzle 410 and the gas supply holes 420a of the nozzle 420. The gas supply holes 410a and the gas supply holes 420a are provided from a lower portion to an upper portion of the inner tube 204. An opening area of each of the gas supply holes 410a and the gas supply holes 420a is the same, and each of the gas supply holes 410a and the gas supply holes 420a is provided at the same pitch. However, the gas supply holes 410a and the gas supply holes 420a are not limited thereto. For example, the opening area of each of the gas supply holes 410a and the gas supply holes 420a may gradually increase from the lower portion to the upper portion of the inner tube 204 to further uniformize a flow rate of the gas supplied through the gas supply holes 410a and the gas supply holes 420a.

The gas supply holes 410a of the nozzle 410 and the gas supply holes 420a of the nozzle 420 are provided from a lower portion to an upper portion of the boat 217 described later. Therefore, the process gas supplied into the process chamber 201 through the gas supply holes 410a and the gas supply holes 420a is supplied onto the wafers 200 accommodated in the boat 217 from the lower portion to the upper portion thereof, that is, an entirety of the wafers 200 accommodated in the boat 217. It is preferable that the nozzles 410 and 420 extend from the lower region to the upper region of the process chamber 201. However, the nozzles 410 and 420 may preferably extend only to the vicinity of a ceiling of the boat 217.

A first reactive gas serving as one of process gases is supplied into the process chamber 201 through the gas supply pipe 310 via the valve 316, the MFC 312 and the valve 314 and the nozzle 410.

A second reactive gas serving as one of the process gases and different from the first reactive gas is supplied into the storage 600 through the gas supply pipe 320 via the valve 326, the MFC 322, the valve 324 and the valve 604. Then, the second reactive gas is stored in the storage 600.

A third reactive gas serving as one of the process gases and different from the first reactive gas and the second reactive gas is supplied into the storage 600 through the gas supply pipe 330 via the valve 336, the MFC 332, the valve 334 and the valve 604. Then, the third reactive gas is stored in the storage 600. The third reactive gas contains one or more elements same as those contained in the second reactive gas. However, a molecular structure of the third reactive gas is different from that of the second reactive gas. Further, as the third reactive gas, for example, a gas whose vapor pressure is lower than that of the second reactive gas may be used.

Further, the second reactive gas and the third reactive gas stored in the storage 600 are supplied through the gas supply pipe 320 into the process chamber 201 via the valve 602 and the nozzle 420.

The inert gas is supplied into the process chamber 201 through the gas supply pipes 510 and 520 provided with the valves 516 and 526, the MFCs 512 and 522 and the valves 514 and 524, respectively, and the nozzles 410 and 420. The present embodiments will be described by way of an example in which nitrogen (N₂) gas is used as the inert gas. However, as the inert gas, for example, instead of or in addition to the nitrogen (N₂) gas, a rare gas such as argon (Ar) gas, helium (He) gas, neon (Ne) gas and xenon (Xe) gas may be used.

When the first reactive gas is supplied mainly through the gas supply pipe 310, a first gas supplier (which is a first gas supply structure or a first gas supply system) is constituted mainly by the gas supply pipe 310, the valve 316, the MFC 312 and the valve 314. However, the first gas supplier may further include the nozzle 410. Further, when the second reactive gas is supplied through the gas supply pipe 320, a second gas supplier (which is a second gas supply structure or a second gas supply system) is constituted mainly by the gas supply pipe 320, the valve 326, the MFC 322 and the valve 324. However, the MFC 322 may be omitted, and the second gas supplier may be constituted by at least the valve 324. Further, when the third reactive gas is supplied through the gas supply pipe 330, a third gas supplier (which is a third gas supply structure or a third gas supply system) is constituted mainly by the gas supply pipe 330, the valve 336, the MFC 332 and the valve 334. However, the MFC 332 may be omitted, and the third gas supplier may be constituted by at least the valve 334. Further, each of the second gas supplier and the third gas supplier may further include the valve 604, the storage 600 and the valve 602. Further, the first gas supplier, the second gas supplier and the third gas supplier may also be collectively referred to as a “gas supply structure”. The gas supply structure may further include the nozzles 410 and 420. In addition, an inert gas supplier (which is an inert gas supply structure or an inert gas supply system) is constituted mainly by the gas supply pipes 510 and 520, the MFCs 512 and 522 and the valves 514 and 524. The gas supply structure may further include the inert gas supplier.

According to the present embodiments, the gas is supplied into a vertically long annular space which is defined by the inner wall of the inner tube 204 and edges (peripheries) of the wafers 200 through the nozzles 410 and 420 provided in the preliminary chamber 201a. Then, the gas is ejected into the inner tube 204 through the gas supply holes 410a of the nozzle 410 and the gas supply holes 420a of the nozzle 420 provided at the positions facing the wafers 200. More specifically, gases such as the first reactive gas, the second reactive gas and the third reactive gas are ejected into the inner tube 204 in a direction parallel to surfaces of the wafers 200 through the gas supply holes 410a of the nozzle 410 and the gas supply holes 420a of the nozzle 420.

An exhaust hole (which is an exhaust port) 204a is a through-hole facing the nozzles 410 and 420, and is provided at a side wall of the inner tube 204. For example, the exhaust hole 204a may be of a narrow slit-shaped through-hole elongating vertically. The gas supplied into the process chamber 201 through the gas supply holes 410a of the nozzle 410 or the gas supply holes 420a of the nozzle 420 flows over the surfaces of the wafers 200. The gas that has flowed over the surfaces of the wafers 200 is exhausted through the exhaust hole 204a into a gap (that is, an exhaust path 206) provided between the inner tube 204 and the outer tube 203. The gas flowing in the exhaust path 206 flows into an exhaust pipe 231 and is then discharged (exhausted) out of the process furnace 202.

The exhaust hole 204a is provided to face the wafers 200. The gas supplied to the vicinity of the wafers 200 in the process chamber 201 through the gas supply holes 410a or the gas supply holes 420a flows in the horizontal direction. The gas that has flowed in the horizontal direction is exhausted through the exhaust hole 204a into the exhaust path 206. The exhaust hole 204a is not limited to the slit-shaped through-hole. For example, the exhaust hole 204a may be configured as a plurality of holes.

The exhaust pipe 231 through which an inner atmosphere of the process chamber 201 is exhausted is installed at the manifold 209. A pressure sensor 245 serving as a pressure detector (pressure detecting structure) configured to detect an inner pressure of the process chamber 201, an APC (Automatic Pressure Controller) valve 243 and a vacuum pump 246 serving as a vacuum exhaust apparatus are sequentially connected to the exhaust pipe 231 in this order from an upstream side to a downstream side of the exhaust pipe 231. With the vacuum pump 246 in operation, the APC valve 243 may be opened or closed to perform a vacuum exhaust of the process chamber 201 or stop the vacuum exhaust. Further, with the vacuum pump 246 in operation, an opening degree of the APC valve 243 may be adjusted in order to adjust the inner pressure of the process chamber 201. An exhauster (which is an exhaust structure or an exhaust system) is constituted mainly by the exhaust hole 204a, the exhaust path 206, the exhaust pipe 231, the APC valve 243 and the pressure sensor 245. The exhauster may further include the vacuum pump 246.

An exhaust pipe 606 through which an inner atmosphere of the storage 600 is exhausted is installed at the storage 600. The exhaust pipe 606 is connected to a location upstream of the APC valve 243 of the exhaust pipe 231. A valve 608 is provided at the exhaust pipe 606. A storage exhauster (which is a storage exhaust structure or a storage exhaust system) serving as an exhauster is constituted mainly by the exhaust pipe 606, the valve 608, the exhaust pipe 231, the APC valve 243, and the pressure sensor 245. The storage exhauster may further include the vacuum pump 246. Further, the storage exhauster may also be referred to as an “exhauster”.

A seal cap 219 serving as a furnace opening lid capable of airtightly sealing a lower end opening of the manifold 209 is provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator (which is a rotating structure) 267 configured to rotate the boat 217 accommodating the wafers 200 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 may be transferred (loaded) into the process chamber 201 or transferred (unloaded) out of the process chamber 201. The boat elevator 115 serves as a transfer device (which is a transfer structure or a transfer system) that loads the boat 217 and the wafers 200 accommodated in the boat 217 into the process chamber 201 or that unloads the boat 217 and the wafers 200 accommodated in the boat 217 out of the process chamber 201.

The boat 217 is configured to accommodate (or support) the wafers 200 (for example, 25 to 200 wafers) while the wafers 200 are horizontally oriented with their centers aligned with one another with a predetermined interval therebetween in the vertical direction. For example, the boat 217 is made of a heat resistant material such as quartz and SiC. A heat insulating cylinder 218 such as a cylinder made of a heat resistant material such as quartz and SiC is provided under the boat 217. With such a configuration, the heat insulating cylinder 218 suppress the transmission of the heat from the heater 207 to the seal cap 219. However, the present embodiments are not limited thereto. For example, instead of the heat insulating cylinder 218, a plurality of dummy substrates (not shown) horizontally oriented may be provided under the boat 217 in a multistage manner. Each of the dummy substrates may be made of a heat resistant material such as quartz and SiC.

As shown in FIG. 2, a temperature sensor 263 serving as a temperature detector is installed in the inner tube 204. An amount of the current supplied (or applied) to the heater 207 is adjusted based on temperature information detected by the temperature sensor 263 such that a desired temperature distribution of an inner temperature of the process chamber 201 can be obtained. Similar to the nozzles 410 and 420, the temperature sensor 263 is L-shaped, and is provided along the inner wall of the inner tube 204.

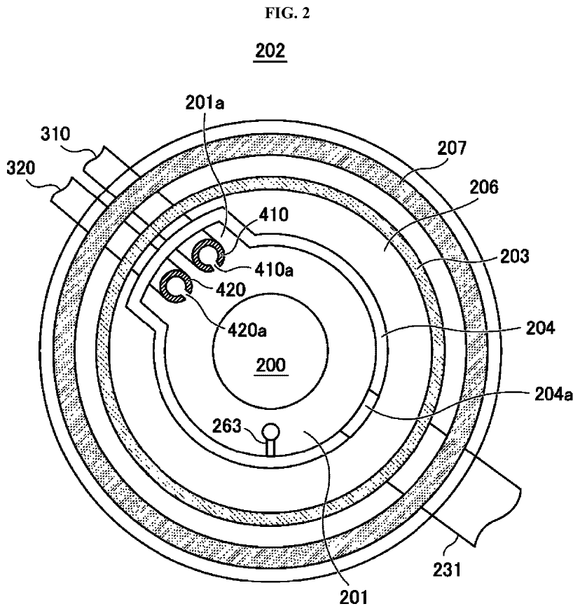

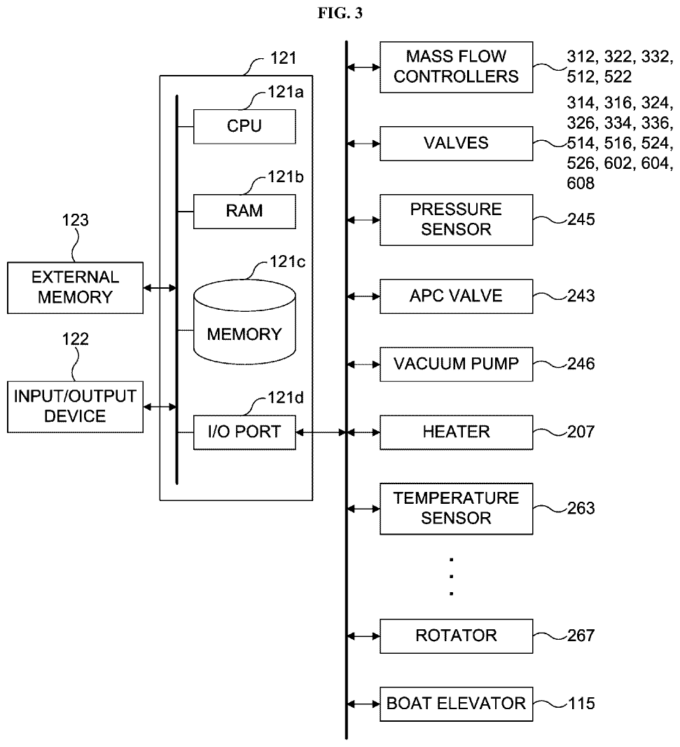

As shown in FIG. 3, a controller 121 serving as a control device (or a control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus. For example, an input/output device 122 constituted by a component such as a touch panel is connected to the controller 121.

The memory 121c is configured by a component such as a flash memory and a hard disk drive (HDD). For example, a control program configured to control an operation of the substrate processing apparatus 10 or a process recipe containing information on sequences and conditions of a method of manufacturing a semiconductor device described later is readably stored in the memory 121c. The process recipe is obtained by combining steps of the method of manufacturing the semiconductor device described later such that the controller 121 can execute the steps to acquire a predetermined result, and functions as a program. Hereafter, the process recipe and the control program may be collectively or individually referred to as a “program”. Thus, in the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components described above such as the MFCs 312, 322, 332, 512 and 522, the valves 314, 316, 324, 326, 334, 336, 514, 516, 524, 526, 602, 604 and 608, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. In accordance with the contents of the read recipe, the CPU 121a may be configured to control various operations such as flow rate adjusting operations for various gases by the MFCs 312, 322, 332, 512 and 522, opening and closing operations of the valves 314, 316, 324, 326, 334, 336, 514, 516, 524, 526, 602, 604 and 608, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-mentioned program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing

Hereinafter, an exemplary process sequence for forming a film on the wafer 200 serving as the substrate using the substrate processing apparatus 10, which is performed as a part of a manufacturing process of a semiconductor device, will be described. In the following description, operations of components constituting the substrate processing apparatus 10 are controlled by the controller 121.

The manufacturing process of the semiconductor device according to the embodiments of the present disclosure may include:
(a) storing the second reactive gas and the third reactive gas in the storage 600 provided at the gas supply pipe 320, wherein the third reactive gas contains an element (or elements) same as that (or those) contained in the second reactive gas and the molecular structure of the third reactive gas is different from that of the second reactive gas;
(b) supplying the first reactive gas to the substrate (that is, the wafer 200) in the process vessel; and
(c) supplying the second reactive gas and the third reactive gas to the substrate by opening the first valve (that is, the valve 602) provided at the gas supply pipe 320 between the storage 600 and the process vessel.

In the present specification, the term “wafer” may refer to “a wafer itself”, or may refer to “a wafer and a stacked structure (aggregated structure) of a predetermined layer (or layers) or a film (or films) formed on a surface of the wafer”. Similarly, the term “a surface of a wafer” may refer to “a surface of a wafer itself”, or may refer to “a surface of a predetermined layer or a film formed on a wafer”. In the present specification, the terms “substrate” and “wafer” may be used as substantially the same meaning.

### Wafer Charging Step and Boat Loading Step

The wafers 200 are charged (transferred) into the boat 217 (wafer charging step). After the boat 217 is charged with the wafers 200, as shown in FIG. 1, the boat 217 charged with the wafers 200 is elevated by the boat elevator 115 and loaded (transferred) into the process chamber 201 (boat loading step). With the boat 217 loaded, the seal cap 219 seals the lower end opening of the outer tube 203 via the O-ring 220b.

Thereafter, the vacuum pump 246 vacuum-exhausts the inner atmosphere of the process chamber 201 (that is, a space in which the wafers 200 are accommodated) such that the inner pressure of the process chamber 201 reaches and is maintained at a desired pressure (vacuum degree). Meanwhile, the inner pressure of the process chamber 201 is measured by the pressure sensor 245, and the APC valve 243 is feedback-controlled based on pressure information detected by the pressure sensor 245 (pressure adjusting step). Further, the heater 207 heats the process chamber 201 such that the inner temperature of the process chamber 201 reaches and is maintained at a desired temperature. Meanwhile, the amount of the current supplied to the heater 207 is feedback-controlled based on the temperature information detected by the temperature sensor 263 such that the desired temperature distribution of the inner temperature of the process chamber 201 is obtained (temperature adjusting step). In addition, the rotator 267 starts rotating the wafers 200. The vacuum pump 246 continuously vacuum-exhausts the inner atmosphere of the process chamber 201, the heater 207 continuously heats the wafer 200 and the rotator 267 continuously rotates the wafer 200 until at least a processing of the wafer 200 is completed.

### Film Forming Process

A film forming process includes the following steps, that is, a first reactive gas supply step S10, a purge step S11, a second and third reactive gas supply step S12 and a purge step S13.

### First Reactive Gas Supply Step S10

The valves 314 and 316 are opened to supply the first reactive gas into the gas supply pipe 310. That is, a process of supplying the first reactive gas to the wafer 200 is performed. A flow rate of the first reactive gas is adjusted by the MFC 312, and the first reactive gas whose flow rate is adjusted is supplied into the process chamber 201 through the gas supply holes 410a of the nozzle 410, and is exhausted through the exhaust pipe 231. In the present step, in parallel with a supply of the first reactive gas, the valves 514 and 516 are opened to supply the inert gas such as the N₂ gas into the gas supply pipe 510. A flow rate of the inert gas flowing through the gas supply pipe 510 is adjusted by the MFC 512, and then the inert gas is supplied into the process chamber 201 together with the first reactive gas, and is exhausted through the exhaust pipe 231. In the present step, in order to prevent the first reactive gas from entering the nozzle 420, the valves 524 and 526 are opened to supply the inert gas into the gas supply pipe 520. The inert gas is supplied into the process chamber 201 through the gas supply pipe 320 and the nozzle 420, and is exhausted through the exhaust pipe 231.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the first reactive gas controlled by the MFC 312 can be set to a flow rate within a range from 0.1 slm to 2.0 slm. For example, each supply flow rate of the inert gas controlled by each of the MFCs 512 and 522 can be set to a flow rate within a range from 0.1 slm to 20 slm. In the present step, for example, a temperature of the heater 207 can be set such that a temperature of the wafer 200 reaches and is maintained at a temperature within a range from 300° C. to 650° C. For example, a supply time (time duration) of supplying the first reactive gas to the wafer 200 can be set to a time within a range from 0.01 second to 30 seconds. In the present specification, a notation of a numerical range such as “from 1 Pa to 3,990 Pa” means that a lower limit and an upper limit are included in the numerical range. Therefore, for example, the numerical range “from 1 Pa to 3,990 Pa” means a range equal to or higher than 1 Pa and equal to or lower than 3,990 Pa. The same also applies to other numerical ranges described herein.

In the present step, the first reactive gas is supplied to the wafers 200. As the first reactive gas, for example, a gas containing titanium (Ti) serving as a metal element may be used. For example, a gas containing a halogen element such as titanium tetrafluoride (TiF₄) gas, titanium tetrachloride (TiCl₄) gas and titanium tetrabromide (TiBr₄) gas may be used as the first reactive gas. As the first reactive gas, for example, one or more of the gases exemplified above may be used.

### Purge Step S11

After a predetermined time has elapsed from the supply of the first reactive gas, the valves 314 and 316 are closed to stop the supply of the first reactive gas. In the present step, with the APC valve 243 of the exhaust pipe 231 open, the vacuum pump 246 vacuum-exhausts the inner atmosphere of the process chamber 201 to remove the first reactive gas (which remains unreacted or already contributed to a formation of the film) remaining in the process chamber 201 from process chamber 201. Further, in the present step, by maintaining the valves 514, 516, 524 and 526 open, the inert gas is continuously supplied into the process chamber 201. The inert gas serves as a purge gas, which improves an efficiency of removing the first reactive gas (which remains unreacted or already contributed to the formation of the film) remaining in the process chamber 201 out of the process chamber 201.

### Second and Third Reactive Gas Supply Step S12

After a predetermined time has elapsed from a start of the purge step S11, the valve 602 is opened to supply the second reactive gas and the third reactive gas from the storage 600 into the gas supply pipe 320. In the storage 600, the second reactive gas and the third reactive gas are stored in advance. An operation of storing the second reactive gas and the third reactive gas in the storage 600 will be described later. The second reactive gas and the third reactive gas are supplied into the process chamber 201 through the gas supply holes 420a of the nozzle 420, and are exhausted through the exhaust pipe 231. In the present step, in parallel with a supply of the second reactive gas and the third reactive gas, the valves 524 and 526 are opened to supply the inert gas into the gas supply pipe 520. In the present step, in order to prevent the second reactive gas and the third reactive gas from entering the nozzle 410, the valves 514 and 516 are opened to supply the inert gas into the gas supply pipe 510.

In the present step, for example, the APC valve 243 is appropriately adjusted (or controlled) such that the inner pressure of the process chamber 201 can be set to a pressure within a range from 1 Pa to 3,990 Pa. For example, each supply flow rate of the inert gas controlled by each of the MFCs 512 and 522 can be set to a flow rate within a range from 0.1 slm to 20 slm. For example, a supply time (time duration) of supplying the second reactive gas and the third reactive gas to the wafer 200 can be set to a time within a range from 0.1 second to 60 seconds.

Thereby, the second reactive gas and the third reactive gas are supplied from the storage 600 to the wafer 200. The second reactive gas and the third reactive gas contain two elements in common between them, for example, a nitrogen (N) element and a hydrogen (H) element. Since the second reactive gas and the third reactive gas contain the two common elements, it is possible to set an amount of each element supplied to the wafer 200 to a predetermined amount. When an element contained in the second reactive gas are different from that contained in the third reactive gas, an amount of the element of the second reactive gas supplied to the wafer 200 may be reduced. In other words, the number of particles of the element of the second reactive gas that contribute to the formation of the film on the wafer 200 may be reduced. By using the second reactive gas and the third reactive gas containing the two common elements, it is possible to set the amount of each element that contributes to the formation of the film on the wafer 200 to the predetermined amount.

As the second reactive gas, for example, a gas containing nitrogen (N) and hydrogen (H) such as a gas containing NH₃ may be used. For example, as the gas containing NH₃, a gas such as ammonia (NH₃) gas may be used.

As the third reactive gas, for example, a gas containing nitrogen (N) and hydrogen (H) such as a gas containing N₂H₄ may be used. For example, as the gas containing N₂H₄, a gas such as hydrazine (N₂H₄) gas may be used. For example, when the N₂H₄ gas is used as the third reactive gas, the MFC 332 may be omitted, and a flow rate of the third reactive gas may be adjusted by bubbling with the N₂ gas and a tank temperature. As the third reactive gas, for example, a gas whose vapor pressure is lower than that of the second reactive gas at the same temperature may be used.

For example, the N₂H₄ gas is more expensive than the NH₃ gas. However, a nitriding power of the N₂H₄ gas is higher than that of the NH₃ gas. Thus, according to the present embodiments, by using the NH₃ gas as the second reactive gas and the N₂H₄ gas as the third reactive gas as disclosed above, it is possible to reduce a consumption of the N₂H₄ gas while maintaining a nitriding effect.

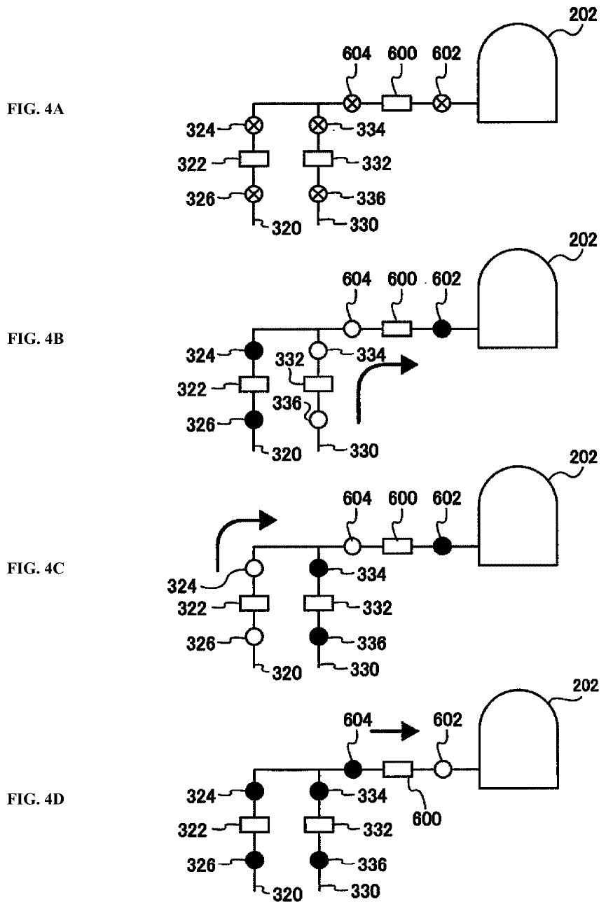

Subsequently, operations of the gas supply structure when storing the second reactive gas and the third reactive gas in the storage 600 before supplying the second reactive gas and the third reactive gas to the wafer 200 will be described with reference to FIGS. 4A to 4D. A process (step) of storing the second reactive gas and the third reactive gas in the storage 600 may be performed before the supply of the first reactive gas in the step S10, may be performed during the supply of the first reactive gas in the step S10 or may be performed during a purge in the step S11. That is, the process is performed before the supply of the second reactive gas and the third reactive gas in the step S12. It is preferable that the process is performed immediately before the step S12. In the valves 324, 326, 334, 336, 602 and 604 in FIGS. 4B to 4D, a black circle related to a valve indicates that the valve related thereto is closed, and a white circle related to a valve indicates that the valve related thereto is open. Further, in FIGS. 4A to 4D, the storage exhauster is not illustrated.

First, the third reactive gas is stored in the storage 600. Specifically, as shown in FIG. 4B, the controller 121 closes the valves 324, 326 and 602 and opens the valves 336, 334 and 604 to supply the third reactive gas into the storage 600. That is, the controller 121 closes the valve 602 to store the third reactive gas in the storage 600. The flow rate of the third reactive gas is adjusted by the MFC 332, and the third reactive gas whose flow rate is adjusted is supplied to the storage 600. For example, a supply flow rate of the third reactive gas controlled by the MFC 332 can be set to a flow rate within a range from 0.1 slm to 2.0 slm.

Subsequently, the second reactive gas is stored in the storage 600. Specifically, as shown in FIG. 4C, with the valve 602 closed and the valve 604 open, the controller 121 closes the valves 334 and 336 and opens the valves 324 and 326 to supply the second reactive gas into the storage 600. A flow rate of the second reactive gas is adjusted by the MFC 322, and the second reactive gas whose flow rate is adjusted is supplied to the storage 600. For example, a supply flow rate of the second reactive gas controlled by the MFC 322 can be set to a flow rate within a range from 0.1 slm to 30 slm.

As described above, the process of storing the second reactive gas and the third reactive gas in the storage 600 is performed by supplying the second reactive gas whose vapor pressure is high to the storage 600 after supplying a predetermined amount of the third reactive gas whose vapor pressure is low to the storage 600. Thus, a predetermined amount of two types of gases with different vapor pressures is stored in the storage 600. First, a predetermined amount of the gas (such as the third reactive gas) whose vapor pressure is low is stored in the storage 600. In the present embodiments, for example, when the NH₃ gas is used as the second reactive gas and the N₂H₄ gas is used as the third reactive gas, the N₂H₄ gas whose vapor pressure is low will decompose at a temperature within a range from 40° C. to 50° C. Therefore, a predetermined amount of the N₂H₄ gas is stored in the storage 600 first, and then the NH₃ gas is stored in the storage 600. In addition, it is preferable to store the NH₃ gas and the N₂H₄ gas in the storage 600 immediately before supplying the NH₃ gas and the N₂H₄ gas to the wafer 200.

Subsequently, as shown in FIG. 4D, with the valves 334 and 336 closed, the controller 121 closes the valves 324, 326 and 604 and opens the valve 602 to simultaneously supply the second reactive gas and the third reactive gas stored in the storage 600 into the process vessel. That is, a process of simultaneously supplying the second reactive gas and the third reactive gas from the storage 600 to the wafer 200 is performed.

When two different types of gases are supplied simultaneously, it may be difficult to set a pressure of each gas before flowing through an MFC related thereto and a pressure of each gas after flowing through the MFC related thereto to a predetermined pressure. Thus, the MFC may not operate normally, and thereby, a flow rate of each gas may vary. However, according to the present embodiments, the flow rate of each gas is adjusted by the MFC related thereto and then each gas is stored in the storage 600. Then, each gas is supplied to the wafer 200 simultaneously. Thereby, it is possible to suppress an occurrence of variations in a processing quality of the wafer 200, and it is also possible to improve the processing quality of the wafer 200.

### Purge Step S13

After a predetermined time has elapsed from the supply of the second reactive gas and the third reactive gas, the valve 602 is closed to stop the supply of the second reactive gas and the third reactive gas from the storage 600. Then, the second reactive gas and the third reactive gas (which remain unreacted or already contributed to the formation of the film) remaining in the process chamber 201 are removed from the process chamber 201 in substantially the same manners as in the purge step S11 described above.

In the present step, the controller 121 opens the valve 608 to exhaust the inner atmosphere of the storage 600 through the exhaust pipes 606 and 231. That is, after the second reactive gas and the third reactive gas are supplied from the storage 600 to the wafer 200, the controller 121 closes the valves 602 and 604 and opens the valve 608 to vacuum-exhaust the inner atmosphere of the storage 600.

Subsequently, the controller 121 closes the valve 608, and performs the process shown in FIG. 4B described above while maintaining the inner atmosphere of the storage 600 at a vacuum state. That is, with the inner atmosphere of the storage 600 maintained at the vacuum state, the controller 121 opens the valves 334, 336 and 604 to supply the third reactive gas into the storage 600. By exhausting the storage 600 to a reduced pressure state, it is possible to store a predetermined amount of the third reactive gas in the storage 600.

### Performing a Predetermined Number of Times

By performing a cycle (in which the step S10 to the step S13 described above are sequentially performed in this order) at least once (that is, a predetermined number of times (n times)), it is possible to form a film with a predetermined thickness on the wafer 200. It is preferable that the cycle described above is repeatedly performed a plurality number of times. According to the present embodiments, for example, a titanium nitride (TiN) film is formed on the wafer 200 as a film containing the metal element.

### After-Purge Step and Returning to Atmospheric Pressure Step

The inert gas is supplied into the process chamber 201 through each of the gas supply pipes 510 and 520, and is exhausted through the exhaust pipe 231. The inert gas serves as the purge gas, and the inner atmosphere of the process chamber 201 is purged with the inert gas. Thus, a residual gas in the process chamber 201 and reaction by-products remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to a normal pressure (atmospheric pressure) (returning to the atmospheric pressure step).

### Boat Unloading Step and Wafer Discharging Step

Thereafter, the seal cap 219 is lowered by the boat elevator 115 and the lower end of the outer tube 203 is opened. The boat 217 with the wafers 200 (which are processed) charged therein (that is, the wafers 200 with a predetermined film formed thereon) is unloaded out of the outer tube 203 through the lower end of the outer tube 203 (boat unloading step). Then, the wafers 200 (which are processed) are discharged (transferred) out of the boat 217 (wafer discharging step).

### (3) Effects According to Present Embodiments

According to the present embodiments, it is possible to obtain one or more of the following effects.
(a) Even when a plurality of different gases are supplied simultaneously, it is possible to improve the processing quality of the wafer 200. That is, since the different gases whose flow rates are adjusted by the MFCs are stored in the storage 600 and then supplied to the wafer 200 simultaneously, it is possible to suppress the occurrence of the variations in the processing quality of the wafer 200, and it is also possible to improve the processing quality of the wafer 200.
(b) That is, by improving the processing quality such as characteristics of the film formed on the wafer 200, it is possible to uniformize the processing quality.
(c) Even when a low vapor pressure gas (that is, the gas whose vapor pressure is low) and a high vapor pressure gas (that is, the gas whose vapor pressure is high) are used for a simultaneous supply, by first storing the low vapor pressure gas in the storage 600 and then storing the high vapor pressure gas in the storage 600, it is possible to supply a sufficient supply amount of the gases into the process furnace 202 in a short time. Therefore, it is possible to suppress the occurrence of the variations in the processing quality of the wafer 200, and it is also possible to improve the processing quality of the wafer 200.

### (4) Modified Examples

The second reactive gas and third reactive gas supply step S12 in the embodiments mentioned above may be modified as in modified examples described below. Unless otherwise specified, configurations in each modified example are substantially the same as those in the embodiments mentioned above, and the description thereof will be omitted.

### First Modified Example

In the present modified example, after a state shown in FIGS. 4B and 4C mentioned above, as shown in FIG. 5, with the valves 604, 324 and 326 open and the valves 334 and 336 closed, the controller 121 opens the valve 602 to supply the second reactive gas and the third reactive gas from the storage 600 to the wafer 200 while the second reactive gas is being supplied to the storage 600. That is, after the state shown in FIG. 4C, the second reactive gas is continuously supplied to the wafer 200. Even in the present modified example, it is possible to obtain substantially the same effects as the embodiments described above.

### Second Modified Example

In the present modified example, after the second reactive gas and the third reactive gas stored in the storage 600 are supplied into the process vessel for a predetermined time in a state shown in FIG. 4D mentioned above, as shown in FIG. 5, with the valve 602 open and the valves 334 and 336 closed, the controller 121 opens the valves 604, 324 and 326 to supply the second reactive gas and the third reactive gas from the storage 600 to the wafer 200 while the second reactive gas is being supplied to the storage 600. That is, after the second reactive gas and the third reactive gas are supplied into the process vessel from the storage 600 for the predetermined time in the state shown in FIG. 4D, the second reactive gas is continuously supplied to the wafer 200. Even in the present modified example, it is possible to obtain substantially the same effects as the embodiments described above.

### Third Modified Example

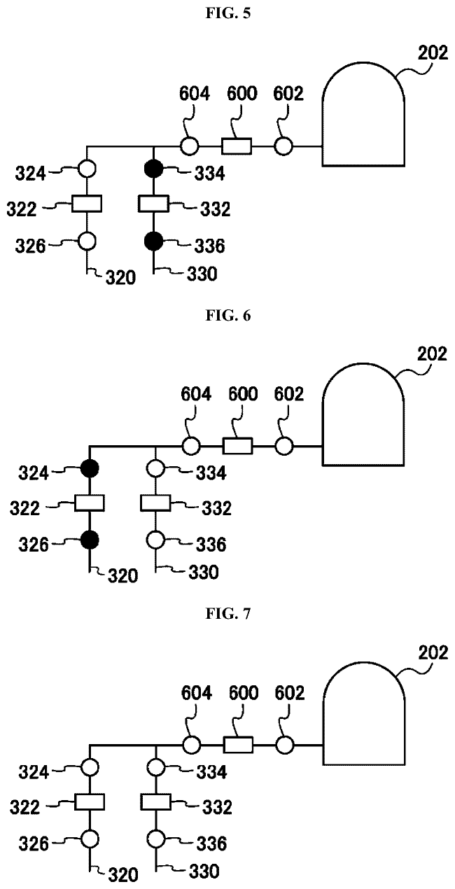

In the present modified example, after the state shown in FIGS. 4B and 4C mentioned above, as shown in FIG. 6, with the valve 604 open, the controller 121 opens the valves 334, 336 and 602 and closes the valves 324 and 326 to supply the second reactive gas and the third reactive gas from the storage 600 to the wafer 200 while the third reactive gas is being supplied to the storage 600. That is, after the state shown in FIG. 4C, the third reactive gas is continuously supplied to the wafer 200. Even in the present modified example, it is possible to obtain substantially the same effects as the embodiments described above.

### Fourth Modified Example

In the present modified example, after the second reactive gas and the third reactive gas stored in the storage 600 are supplied into the process vessel for a predetermined time in the state shown in FIG. 4D mentioned above, as shown in FIG. 6, with the valve 602 open and the valves 324 and 326 closed, the controller 121 opens the valves 604, 334 and 336 to supply the third reactive gas to the wafer 200. That is, after the second reactive gas and the third reactive gas are supplied into the process vessel from the storage 600 for the predetermined time in the state shown in FIG. 4D, the third reactive gas is supplied to the wafer 200. Even in the present modified example, it is possible to obtain substantially the same effects as the embodiments described above.

### Fifth Modified Example

In the present modified example, after the state shown in FIGS. 4B and 4C mentioned above, as shown in FIG. 7, with the valves 604, 324 and 326 open, the controller 121 opens the valves 602, 334 and 336 to supply the second reactive gas and the third reactive gas from the storage 600 to the wafer 200 while the second reactive gas and the third reactive gas are being supplied to the storage 600. Even in the present modified example, it is possible to obtain substantially the same effects as the embodiments described above.

### Sixth Modified Example

In the present modified example, after the second reactive gas and the third reactive gas stored in the storage 600 are supplied into the process vessel for a predetermined time in the state shown in FIG. 4D mentioned above, as shown in FIG. 7, with the valve 602 open, the controller 121 opens the valves 604, 324, 326, 334 and 336 to supply the second reactive gas and the third reactive gas to the wafer 200. That is, after the second reactive gas and the third reactive gas are supplied into the process vessel from the storage 600 for the predetermined time in the state shown in FIG. 4D, the second reactive gas and the third reactive gas is supplied to the wafer 200 through the second gas supplier and the third gas supplier. Even in the present modified example, it is possible to obtain substantially the same effects as the embodiments described above.

### Other Embodiments of Present Disclosure

For example, the embodiments mentioned above are described by way of an example in which the storage 600 is connected to the exhaust pipe 231. However, the technique of the present disclosure is not limited thereto. For example, the inner atmosphere of the storage 600 may be exhausted via the process furnace 202, or a separate exhaust line may be provided to exhaust the inner atmosphere of the storage 600.

For example, the embodiments described above are described by way of an example in which the TiCl₄ gas is used as the first reactive gas, the NH₃ gas is used as the second reactive gas, and the N₂H₄ gas is used as the third reactive gas. However, the technique of the present disclosure is not limited thereto. For example, as the first reactive gas, a gas containing a metal element other than titanium (Ti) (in particular a transition metal element) may be used. Further, as the first reactive gas, a gas containing an element of Group 13 or Group 14 of the periodic table. By using the first reactive gas containing the elements exemplified above, it is possible to form a nitride film. For example, by using a gas containing aluminum (Al) as the first reactive gas, it is possible to form an aluminum nitride (AlN) film. For example, by using a gas containing silicon (Si) as the first reactive gas, it is possible to form a silicon nitride (SiN) film.

For example, the embodiments described above are described by way of an example in which a vertical batch type substrate processing apparatus configured to simultaneously process a plurality of substrates is used to form the film. However, the technique of the present disclosure is not limited thereto. For example, the technique of the present disclosure may be preferably applied when a single wafer type substrate processing apparatus configured to process one or several substrates at a time is used to form the film.

It is preferable that the process recipe (that is, a program defining parameters such as process sequences and process conditions of the substrate processing) used to form each type of film is prepared individually in accordance with the contents of the substrate processing such as a type of the film to be formed, a composition ratio of the film, a quality of the film, a thickness of the film, the process sequences and the process conditions of the substrate processing. That is, a plurality of process recipes are prepared in advance. Then, when starting the substrate processing, an appropriate process recipe is preferably selected among the process recipes in accordance with the contents of the substrate processing. Specifically, it is preferable that the process recipes are stored (installed) in the memory 121c of the substrate processing apparatus in advance via an electric communication line or the recording medium (for example, the external memory 123) storing the process recipes prepared individually in accordance with the contents of the substrate processing. Then, when starting the substrate processing, the CPU 121a preferably selects the appropriate process recipe among the process recipes stored in the memory 121c of the substrate processing apparatus in accordance with the contents of the substrate processing. With such a configuration, various films of different types, different composition ratios, different qualities and different thicknesses may be universally formed with a high reproducibility using a single substrate processing apparatus. In addition, since a burden on an operator such as inputting the process sequences and the process conditions may be reduced, various processes (that is, the substrate processing) can be performed quickly while avoiding a misoperation of the apparatus.

Further, the technique of the present disclosure may be implemented by changing an existing process recipe stored in the substrate processing apparatus to a new process recipe. When changing the existing process recipe to the new process recipe, the new process recipe according to the technique of the present disclosure may be installed in the substrate processing apparatus via the electric communication line or the recording medium storing the process recipes. Alternatively, the existing process recipe already stored in the substrate processing apparatus may be directly changed to the new process recipe according to the technique of the present disclosure by operating the input/output device of the substrate processing apparatus.

The technique of the present disclosure is described in detail by way of the embodiments and the modified examples described above. However, the technique of the present disclosure is not limited thereto. The technique of the present disclosure may be modified in various ways without departing from the scope thereof.

According to some embodiments of the present disclosure, it is possible to improve the processing quality of the substrate even when the plurality of different gases are supplied simultaneously.

What is claimed is:

1. A substrate processing apparatus comprising:
a process vessel configured to accommodate a substrate;
a first gas supplier configured to supply a first reactive gas into the process vessel;
a gas supply pipe through which a second reactive gas and a third reactive gas are supplied into the process vessel, wherein the third reactive gas contains an element same as that contained in the second reactive gas and a molecular structure of the third reactive gas is different from that of the second reactive gas;
a storage provided at the gas supply pipe and configured to store the second reactive gas and the third reactive gas;
a first valve provided at the gas supply pipe between the storage and the process vessel;
a second gas supplier configured to supply the second reactive gas into the storage;
a third gas supplier configured to supply the third reactive gas into the storage; and
a controller configured to be capable of controlling the first gas supplier, the first valve, the second gas supplier and the third gas supplier to perform:
(a) storing the second reactive gas and the third reactive gas in the storage;
(b) supplying the first reactive gas to the substrate; and
(c) supplying the second reactive gas and the third reactive gas to the substrate from the storage.

2. The substrate processing apparatus of claim 1, wherein the controller is further configured to be capable of controlling the first valve, the second gas supplier and the third gas supplier to store the second reactive gas in the storage after storing the third reactive gas in the storage by closing the first valve.

3. The substrate processing apparatus of claim 2, wherein the controller is further configured to be capable of controlling the first valve, the second gas supplier and the third gas supplier to supply the second reactive gas to the storage after supplying a predetermined amount of the third reactive gas to the storage.

4. The substrate processing apparatus of claim 1, wherein a vapor pressure of the third reactive gas is set to be lower than a vapor pressure of the second reactive gas.

5. The substrate processing apparatus of claim 2, wherein a vapor pressure of the third reactive gas is set to be lower than a vapor pressure of the second reactive gas.

6. The substrate processing apparatus of claim 3, wherein a vapor pressure of the third reactive gas is set to be lower than a vapor pressure of the second reactive gas.

7. The substrate processing apparatus of claim 1, wherein the second reactive gas and the third reactive gas contain two elements in common therebetween.

8. The substrate processing apparatus of claim 1, wherein each of the second reactive gas and the third reactive gas contains a nitrogen element and a hydrogen element.

9. The substrate processing apparatus of claim 1, wherein the second reactive gas contains NH₃ and the third reactive gas contains N₂H₄.

10. The substrate processing apparatus of claim 1, further comprising
a second valve provided at the gas supply pipe upstream of the storage.

11. The substrate processing apparatus of claim 10, wherein the controller is further configured to be capable of controlling the second valve to be opened in (c).

12. The substrate processing apparatus of claim 10, wherein the controller is further configured to be capable of controlling the second valve to be opened after (c).

13. The substrate processing apparatus of claim 11, wherein the controller is further configured to be capable of controlling the second gas supplier to supply the second reactive gas to the substrate with the second valve open.

14. The substrate processing apparatus of claim 11, wherein the controller is further configured to be capable of controlling the third gas supplier to supply the third reactive gas to the substrate with the second valve open.

15. The substrate processing apparatus of claim 1, wherein the controller is further configured to be capable of controlling the first gas supplier, the first valve, the second gas supplier and the third gas supplier to perform (a) before (c).

16. The substrate processing apparatus of claim 1, further comprising
an exhauster configured to exhaust an inner atmosphere of the storage,
wherein the controller is further configured to be capable of controlling the exhauster to perform (d) exhausting the inner atmosphere of the storage after (c).

17. A substrate processing method comprising:
(a) storing a second reactive gas and a third reactive gas in a storage provided at a gas supply pipe, wherein the third reactive gas contains an element same as that contained in the second reactive gas and a molecular structure of the third reactive gas is different from that of the second reactive gas;
(b) supplying a first reactive gas to a substrate in a process vessel; and
(c) supplying the second reactive gas and the third reactive gas to the substrate by opening a first valve provided at the gas supply pipe between the storage and the process vessel.

18. A method of manufacturing a semiconductor device, comprising
the substrate processing method of claim 17.

19. A non-transitory computer-readable recording medium storing a program that causes a substrate processing apparatus, by a computer, to perform:
(a) storing a second reactive gas and a third reactive gas in a storage provided at a gas supply pipe, wherein the third reactive gas contains an element same as that contained in the second reactive gas and a molecular structure of the third reactive gas is different from that of the second reactive gas;
(b) supplying a first reactive gas to a substrate in a process vessel; and
(c) supplying the second reactive gas and the third reactive gas to the substrate by opening a first valve provided at the gas supply pipe between the storage and the process vessel.
